(19) United States
(12) Patent Application Publication
(10) Pub. No.: US 2009/0136741 A1
(43) Pub. Date: May 28, 2009

(54) NANOSCOPICALLY MODIFIED SUPERHYDROPHOBIC COATING

(75) Inventors: Minjuan Zhang, Ann Arbor, MI (US); Debasish Banerjee, Ann Arbor, MI (US); Masahiko Ishii, Okazaki (JP)

Correspondence Address: GIFFORD, KRASS, SPRINKLE,;ANDERSON & CITKOWSKI, P.C., P.O. BOX 7021, TROY, MI, 48007-7021, US

(73) Assignee: Toyota Motor Engineering & Manufacturing North America, Inc., Erlanger, KY (US)

(21) Appl. No.: 11/946,592

(22) Filed: Nov. 28, 2007

(51) Int. Cl. B32B 5/16; H01L 21/316

(52) U.S. Cl. 428/328; 106/287.18

(57) ABSTRACT

A process of forming a clear coat including the steps of providing hydrophobic nanoparticles by chemically modifying the surface of the nanoparticles, dispersing the hydrophobic nanoparticles in a solvent, combining the dispersed nanoparticles in the solvent with a clear coat material, and mixing the dispersed nanoparticles in a solvent with the clear coat material forming a clear coat having a transparency of at least 50 percent.

### FIELD OF THE INVENTION

The Invention relates to a superhydrophobic coating and process for producing a superhydrophobic coating.

### BACKGROUND OF THE INVENTION

Coating compositions may have various applications in the art including using the coating as a paint or varnish, as well as a protective coating or coating aiding the properties of a substrate. Applications of such coatings are diverse and may be used in various applications including painting of structures or vehicles including cars, ships, and large construction objects such as bridges or other such entities.

Hydrophobic coatings have been proposed in the art to develop a self-cleaning effect on a surface of a substrate. For example coatings and systems have been studied in relation to the lotus leaf that includes a hydrophobic material and pyramid shaped structure such that drops of water contact only the tips or peaks of the structure resulting in a reduced surface area having a low adhesion between the water drops and the surface of the lotus leaf.

Coatings have been developed to attempt to present a similar hydrophobic self-cleaning type effect. However, such coatings and processes are limited in that they result in coatings having low abrasion resistance, as well as nondesirable visual qualities.

There is therefore a need in the art for a hydrophobic coating and process for making the coating having improved physical and visual characteristics.

There is also a need in the art for a hydrophobic coating that may be incorporated into a paint system such that the paint system exhibits high hydrophobicity as well as self-cleaning and resistance to the environment, as well as provides improved visual characteristics.

### SUMMARY OF THE INVENTION

In a first aspect, there is disclosed a process of forming a clear coat including the steps of: providing hydrophobic nanoparticles, dispersing the hydrophobic nanoparticles in a solvent, combining the dispersed nanoparticles in the solvent with a clear coat material, and mixing the dispersed nanoparticles in a solvent with the clear coat material forming a clear coat having a transparency of at least 50 percent.

In another aspect, there is also disclosed a clear coat composition including a first component having hydrophobic nanoparticles mixed with a second component including a clear coat material forming a hydrophobic clear coat having a transparency of at least 50 percent.

In another aspect, there is disclosed a paint system for a vehicle including a vehicle substrate material, a base coat applied to the substrate and a clear coat layer applied to the base coat, the clear coat including a first component having hydrophobic nanoparticles mixed with a second component including a clear coat material forming a hydrophobic clear coat having a transparency of at least 50 percent.

In another aspect there is disclosed a clear coat composition including nanoparticles dispersed in a first component of a two part clear coat system combined with a second component of the two part clear coat forming a hydrophobic clear coat having a transparency of at least 50 percent.

In another aspect, there is also disclosed a clear coat composition including a first component having a mixture of differing sized hydrophobic nanoparticles mixed with a second component including a clear coat material forming a hydrophobic clear coat having a transparency of at least 50 percent.

### BRIEF DESCRIPTION OF THE DRAWINGS

FIG. 1 is a diagram of a process for mixing nanoparticles to a clear coat;

FIG. 2 is a graph of the contact angle and transparency of a first example as a percentage of the particle dry volume percent;

FIG. 3 is a graph of the contact angle and transparency as a function of the particle dry volume percentage for a second example;

FIG. 4 is TEM images of a sample of the second example detailing the nanoparticles;

FIG. 5 is a graph of the contact angle and transparency as a function of the particle dry volume percentage for a third example;

FIG. 6 is a depiction of the contact angle measurement;

FIG. 7 details a water droplet on a modified and unmodified surface and shows the hydrophobic character of the surface modified particles described in example 4;

FIG. 8 (a) is a graph of an FTIR measurement of surface modified particles in example 4;

FIG. 8(b) is a depiction of the contact angle measurement of a sample described in example 4;

FIG. 9 is a graphical depiction of mixing particles of multiple sizes as described in example 5;

FIG. 10 is a depiction of the contact angle measurement of a sample described in example 5

FIG. 11 is a diagram of one embodiment of nanoparticles having differing sizes.

### DETAILED DESCRIPTION OF THE PREFERRED EMBODIMENTS

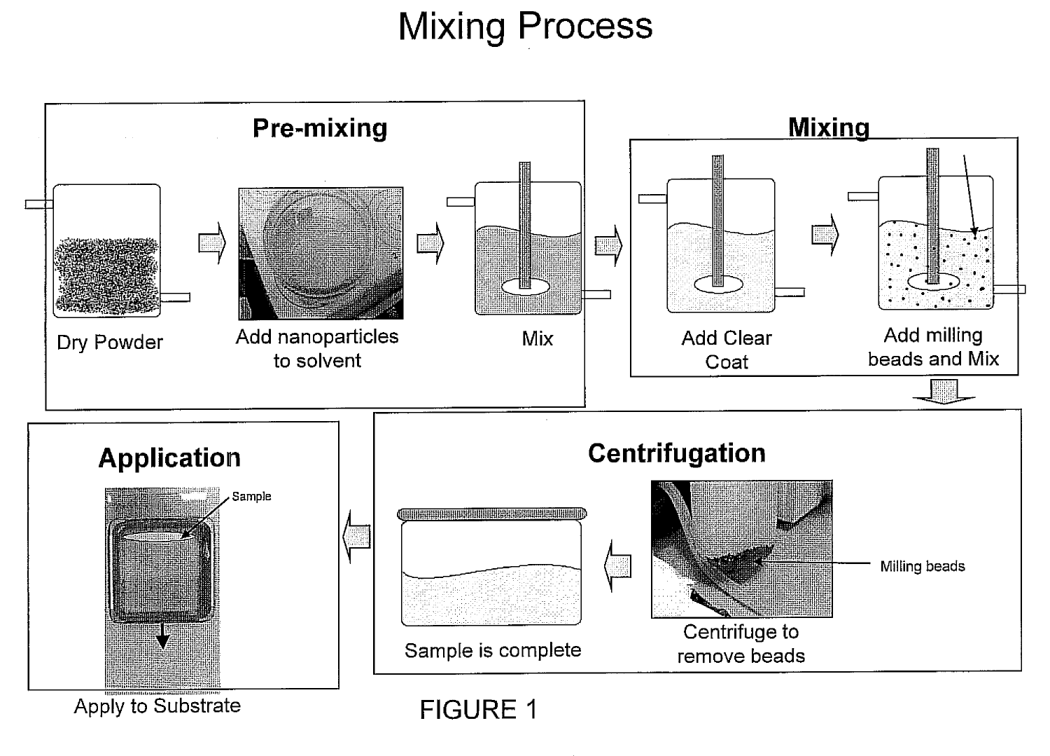

In one aspect, and as disclosed in FIG. 1, there is provided a process of forming a clear coat that includes providing hydrophobic nanoparticles, dispersing the hydrophobic nanoparticles in a solvent, combining the dispersed nanoparticles in a solvent with a clear coat material, and mixing the dispersed nanoparticles in a solvent with a clear coat material to form a clear coat that has a transparency of at least 50 percent.

The hydrophobic nanoparticles may include metal oxide, silicon oxide or silica nanoparticles having a surface modifying group attached to the nanoparticle. In one aspect, the surface modifying group may be selected from the group consisting of silanes, siloxanes or silazanes. Various commercial nanoparticles are available and include silica particles having various silane and silica containing groups attached to the surface of the nanoparticle. Examples of various nanoparticles include various silica powders such as OX50, Aerosil 200 available from and Aerosil 380 available from Degussa corp. These nanoparticles may be reacted with various silicon containing compositions to form a hydrophobic nanoparticle.

Commercially available hydrophobic nanoparticles may be purchased from various sources including Degussa as well as other manufacturers and include nanoparticles having hydrophobic groups or surface modifying groups attached to the nanoparticle. Such nanoparticles are typically manufactured using a gas phase reaction that covalently bonds the surface modifying group to the nanoparticle. Specific examples of commercially available particles will be described in more detail in the example section.

In one aspect, the hydrophobic nanoparticles may have a size of from 5 to 20 nanometers and have a surface area of up to 380 square meters per gram. The hydrophobic nanoparticles may be formed in the commercial gas phase preparations described above or may be formed by a liquid phase reaction including the steps of providing a metal oxide or silicon oxide nanoparticle, dispersing the nanoparticles in a solvent, reacting the nanoparticles in the solvent with a surface modifying reactant forming hydrophobic nanoparticles, and then washing the hydrophobic nanoparticles removing excess reactants. It has been found that the liquid phase reaction for forming the nanoparticles may be advantageous in providing nanoparticles having less aggregation and improving the properties of a coating.

In one aspect, and as described above, the surface modifying groups may include various silicon containing compositions including silanes, siloxanes, and silazanes that react to form a non-polar group attached to the nanoparticle. In this manner, the group provides a hydrophobic property to the nanoparticle. In one aspect, the hydrophobic nanoparticles are dispersed in a solvent following the step of providing the hydrophobic nanoparticle. The solvent may be a solvent compatible with the surface modifying reactant and may be a non-polar solvent. Various examples of solvents include hexane, paint thinner, lacquer thinner, toluene, as well as various other mixtures and combinations of various solvents. While various solvents are listed, it is to be understood that any number of solvents may be utilized that are compatible with both the hydrophobic nanoparticle and the clear coat material. Additionally, the solvent described above with reference to dispersing of the hydrophobic nanoparticles before combining with a clear coat material may be the same or different from a solvent as described above with reference to preparation of the hydrophobic nanoparticles. The solvent again may be any suitable solvent for suspending the nanoparticles and allowing a liquid phase reaction with a surface modifying reactant.

The dispersion of the hydrophobic nanoparticles in a solvent prior to combining the dispersed particles in a solvent with the clear coat material provides for the dispersion of the nanoparticles without aggregation of the particles when combined with the clear coat material. After the clear coat and dispersed nanoparticles in the solvent have been combined, they are mixed under conditions and for a time period such that they form a clear coat having a transparency of at least 50 percent that remains stable after the mixing operation, as well as has a contact angle of at least 130 degrees.

Various mixing techniques including stirring with various mixing devices at different rpms, as well as adding milling beads or other stirring mechanisms, may be used by the invention. When such mixing beads are utilized, they may be removed before the clear coat is used.

In one aspect, the clear coat may have a nanoparticle concentration of from 20 to 60 percent by volume. Various nanoparticle concentrations may be used for the various nanoparticles as well as surface groups that may be used in the process. In one aspect, it has been found that loading concentrations of nanoparticles of from 20 to 60 percent by volume provide sufficient concentrations to allow the contact angle to be maintained at least at 130 degrees. Concentrations of nanoparticles above the upper threshold may provide problems for a transparency to be maintained. Additionally, higher concentrations of nanoparticles may affect the rheology or viscosity of clear coat systems and lead to applications of a clear coat having undesirable properties leading to coatings having less than ideal surface characteristics and properties.

In another aspect, there is disclosed a clear coat composition that includes a first component having hydrophobic nanoparticles mixed with a second component that includes a clear coat material forming a hydrophobic clear coat having a transparency of at least 50 percent. As described above, the clear coat may have a contact angle of at least 130 degrees thereby providing self-cleaning properties to a coating. As previously described, the clear coat may have a nanoparticle concentration of from 20 to 60 percent by volume and have a nanoparticle size of from 5 to 20 nanometers. As previously described with reference to the process, the hydrophobic particles may be metal oxide, silicon oxide or silica nanoparticles having a surface modifying group attached to the nanoparticle. This surface modifying group may include silanes, siloxanes and silazanes.

In another aspect there is disclosed an alternative clear coat composition that includes a two part clear coat. The two part clear coat may include a first part having a resin and a second part having an isocyanide for cross linking with the resin. The hydrophobic nanoparticles may be dispersed in either of the first or second parts and mixed with the other part forming a hydrophobic clear coat having a transparency of at least 50 percent. The hydrophobic nanoparticles may be those described above with respect to the process and previously described clear coat composition. As described above, the clear coat composition may have a contact angle of at least 130 degrees and have a nanoparticle concentration of from 20 to 60 percent by volume and have a nanoparticle size of from 5 to 20 nanometers. As previously described with reference to the process, the hydrophobic particles may be metal oxide, silicon oxide or silica nanoparticles having a surface modifying group attached to the nanoparticles. This surface modifying group may include silanes, siloxanes and silazanes.

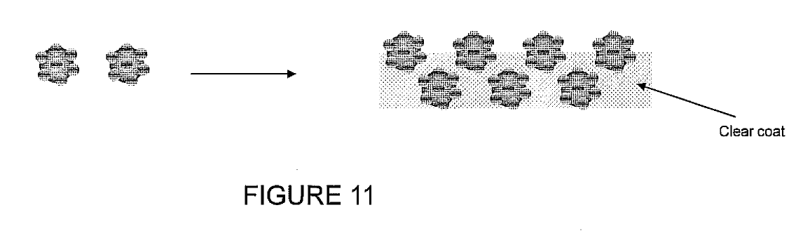

In another aspect there is disclosed another alternative clear coat composition. The clear coat composition includes varying sized hydrophobic particles. The particles may include hydrophobic nanoparticles of differing size. The differing sized hydrophobic nanoparticles may be mixed with a second component that includes a clear coat material forming a hydrophobic clear coat having a transparency of at least 50 percent. The differing sized hydrophobic nanoparticles may also be dispersed in either of the first or second parts of the two part clear coat described above and mixed with the other part forming a hydrophobic clear coat having a transparency of at least 50 percent. The hydrophobic nanoparticles may be those described above with respect to the process and previously described clear coat composition. The hydrophobic nanoparticles may also be an aggregation of the nanoparticles having larger overall particle sizes than the non-aggregated particles. The differing sized particles may have sizes ranging from several nanometers to several hundred micrometers. Additionally, the differing sized nanoparticles may be a combination of surface modified nanoparticles and pigments. In this manner surface modified nanoparticles may be mixed with microsized pigments and a clear coat to form a hydrophobic Matte clear coat. The differing sized nanoparticles may have a core structure with additional particles positioned about the core, as shown in FIG. 11.

As described above, the clear coat composition may have a contact angle of at least 130 degrees and have a nanoparticle concentration of from 20 to 60 percent by volume and have a nanoparticle size of from 5 to 20 nanometers. As previously described with reference to the process, the hydrophobic particles may be metal oxide, silicon oxide or silica nanoparticles having a surface modifying group attached to the nanoparticle. This surface modifying group may include silanes, siloxanes and silazanes.

In another aspect, a paint system for a vehicle may include a vehicle substrate material, a base coat applied to the substrate, and a clear coat layer applied to the base coat. The clear coat may include a first component having hydrophobic nanoparticles mixed with a second component including a clear coat material to form a hydrophobic clear coat having a transparency of at least 50 percent. The clear coat preferably has a contact angle of at least 130 degrees providing a self-cleaning surface for the paint system.

As with the previously described clear coat system, the clear coat may have nanoparticle concentrations of from 20 to 60 percent by volume as well as have nanoparticle sizes of from 5 to 20 nanometers. The nanoparticles may be metal oxide, silicon oxide or silica nanoparticles having a surface modifying group attached to the nanoparticle. The surface modifying group may include silanes, siloxanes, and silazanes.

### EXAMPLES

In the experiments detailed in the examples section, various hydrophobic nanoparticles were dispersed in various solvents and mixed with clear coat materials. The resulting clear coat composition was applied to the surface of a glass or acrylic substrate to evaluate the transparency and contact angle. Below is a table listing some of the nanoparticle and surface modifying groups of various samples.

TABLE 1

| Particle Type | Core size | Surface Modifying Agent |
|---|---|---|
| LE1 | 12 nm | Hexamethyl-di-silazane (HMDS) |
| LE2 | 7 nm | Hexamethyl-di-silazane (HMDS) |
| LE3 | 16 nm | Poly-dimethyl-siloxane (PDMS) |

TABLE 2

| Sample | | Loading | | Contact | |
|---|---|---|---|---|---|
| type | Solvent | (wet wt %) | Thickness | Angle | Transparency |
| LE1 | Toluene | 40% | ~50 um | 143.54 | 88.41 |
| LE1 | Thinner | 40% | ~50 um | 149.13 | 92.75 |
| LE2 | Thinner | 25% | ~50 um | 150.13 | 90.73 |
| LE2 | Thinner | 30% | ~50 um | 154.61 | 80.02 |
| LE3 | Toluene | 15.50% | ~10 um | 154.3 | 81.8 |

### Example 1

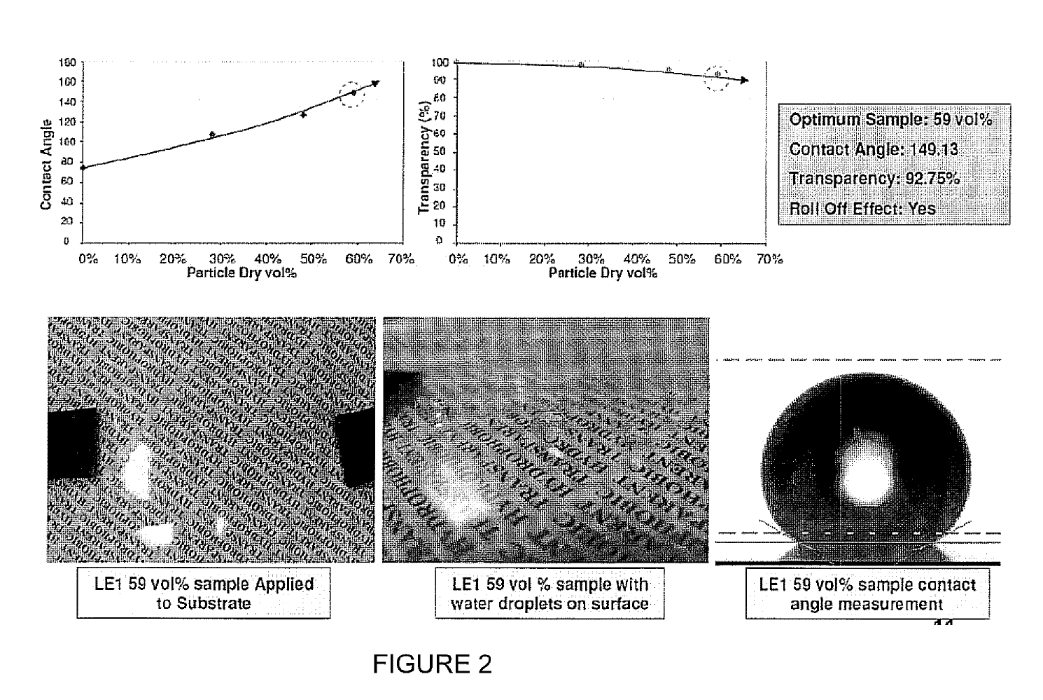

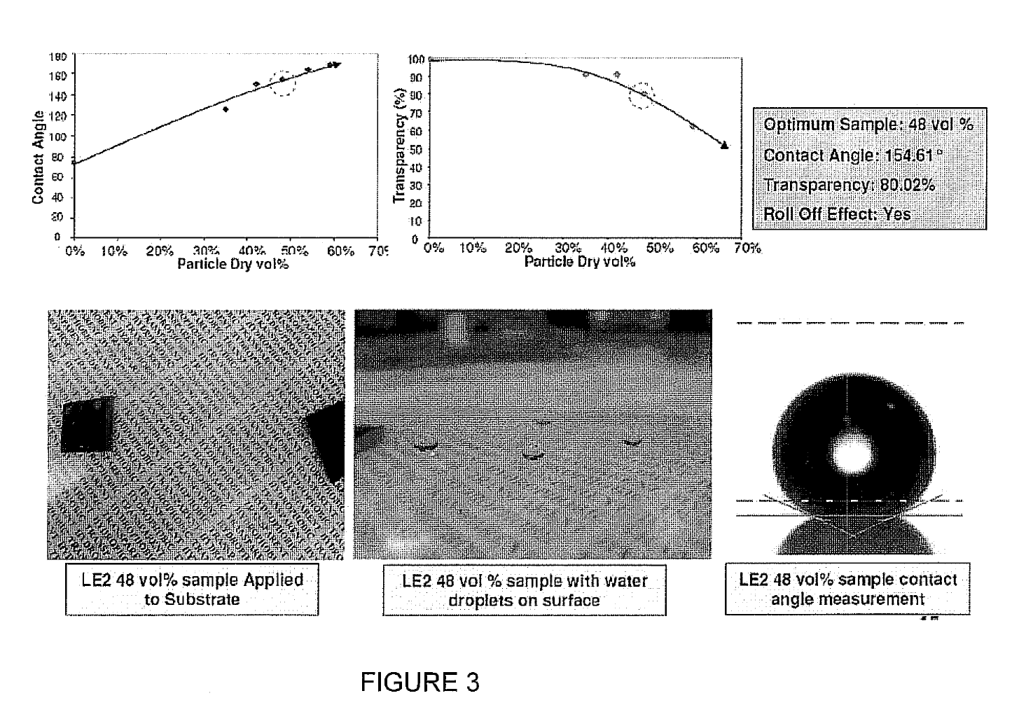

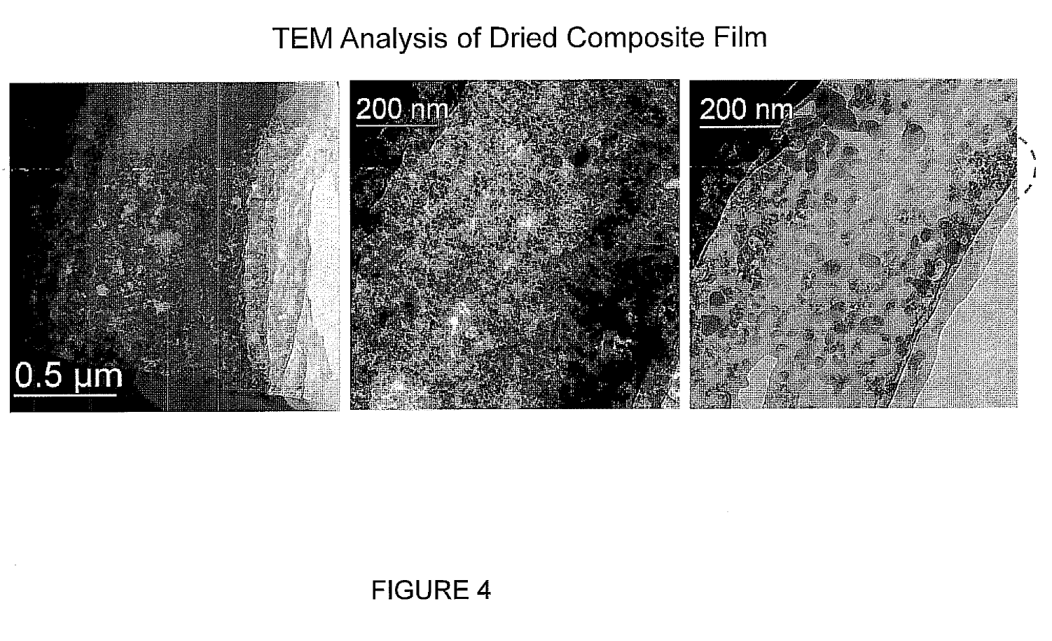

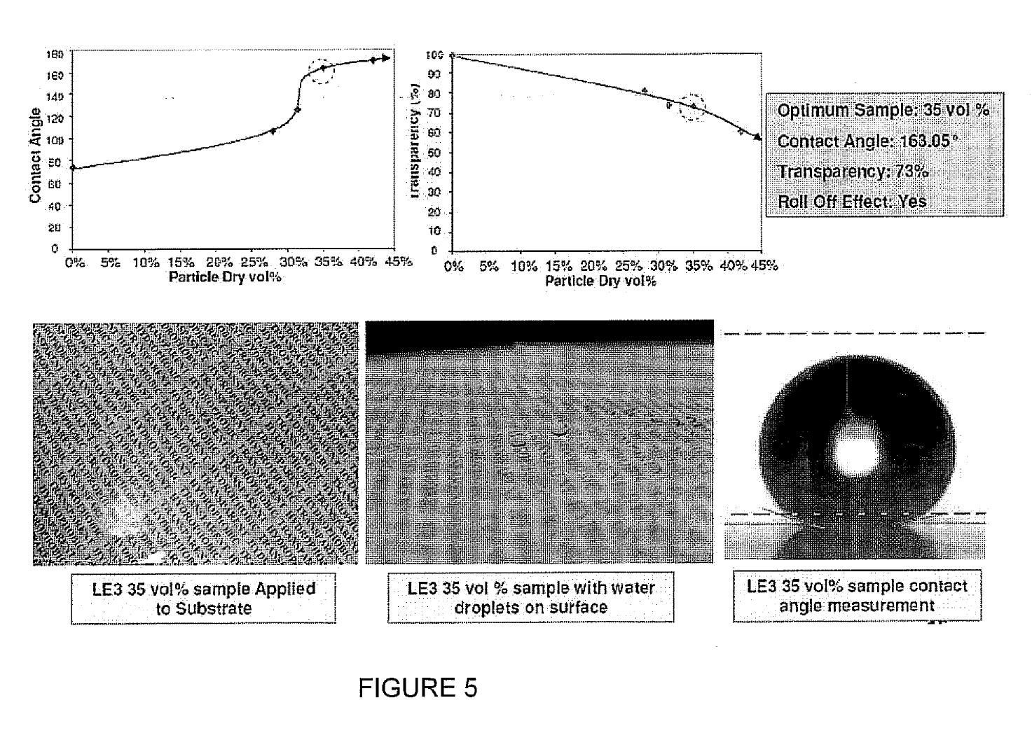

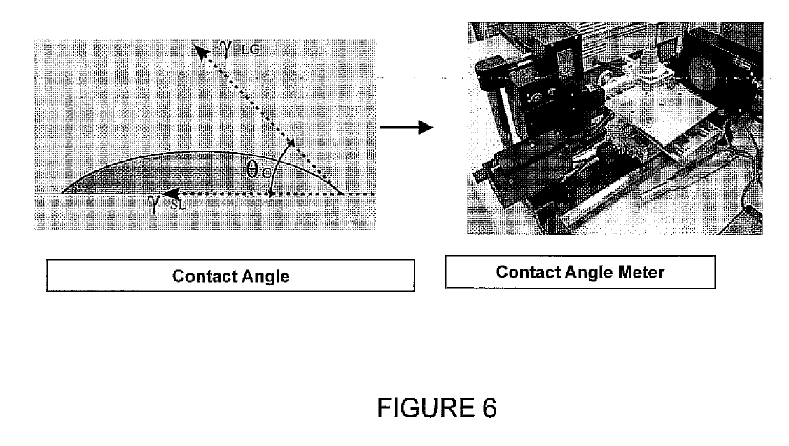

A sample of a LE1, a hydrophobic nanoparticle having a HDMS surface modifying group was dispersed in a solvent. Both toluene and paint thinner were used as solvents. The dispersed mixture was then mixed to disperse the nanoparticles. In the example the solvents and nanoparticles were mixed using a rotary mixer at 3500 rpm for 10 to 15 minutes. The dispersed mixture was then mixed with a clear coat material and mixed for one minute at 2000 rpm with a rotary mixer. Then the mixture was mixed using milling beads at 3500 rpm for 15 minutes. The milling beads were removed in a centrifuge and the samples were applied to a glass substrate for testing. The transparency was measured using a UV-visible spectrophotometer at visible wavelengths. The contact angle was measured using a contact angle meter with appropriate software to calculate the angle as shown in FIG. 6. As can be seen from the data in Table 2 and in FIG. 2, the LE1 sample at 40% loading had contact angles exceeding 140 degrees and had a transparency of greater than 80 percent.

### Example 2

A sample of a LE2, a hydrophobic nanoparticle having a HDMS surface modifying group was dispersed in a solvent. Paint thinner was used as a solvent. The dispersed mixture was then mixed to disperse the nanoparticles. In the example the solvents and nanoparticles were mixed using a rotary mixer at 3500 rpm for 10 to 15 minutes. The dispersed mixture was then mixed with a clear coat material and mixed for one minute at 2000 rpm with a rotary mixer. Then the mixture was mixed using milling beads at 3500 rpm for 15 minutes. The milling beads were removed in a centrifuge and the samples were applied to a glass substrate for testing. The transparency was measured using a UV-visible spectrophotometer at visible wavelengths. The contact angle was measured using a contact angle meter with appropriate software to calculate the angle as shown in FIG. 6 As can be seen from the data in Table 2, the LE2 sample at 25 and 35% loading had contact angles exceeding 140 and a transparency of greater than 80 percent.

### Example 3

A sample of a LE3, a hydrophobic nanoparticle having a PDMS surface modifying group was dispersed in a solvent. Toluene was used as a solvent. The dispersed mixture was then mixed to disperse the nanoparticles. In the example the solvents and nanoparticles were mixed using a rotary mixer at 3500 rpm for 10 to 15 minutes. The dispersed mixture was then mixed with a clear coat material and mixed for one minute at 2000 rpm with a rotary mixer. Then the mixture was mixed using milling beads at 3500 rpm for 15 minutes. The milling beads were removed in a centrifuge and the samples were applied to a glass substrate for testing. The transparency was measured using a UV-visible spectrophotometer at visible wavelengths. The contact angle was measured using a contact angle meter with appropriate software to calculate the angle as shown in FIG. 6. As can be seen from the data in Table 2, the LE3 sample at 15.5% loading had contact angles exceeding 140 and a transparency of greater than 80 percent.

### Example 4

As described above, commercially available nanoparticles are often generated through a vapor phase process that produces generally larger aggregations on the order of over a few hundred nanometers which may be more difficult to fully disperse with a clear coat. Poor dispersion may result in a lesser transparency of a clear coat composition. Commercially available unmodified silica nanoparticles may be surface modified using a liquid phase reaction to reduce the particle size. Inorganic nanoparticles having extremely high surface area may be nanoparticles with an average diameter less than 20 mm. When dispersed in a solvent of compatible polarity, the particles may be dispersed to generate a transparent clear liquid indicating smaller sizes of nanoparticles. The surface of these nanoparticles are chemically modified by covalently attaching non-polar groups in solution phase reaction. In solution, the nanoparticles remain dispersed after the reaction. In order to maintain the stable well-dispersed condition they are mixed with the clearcoat system while in solution.

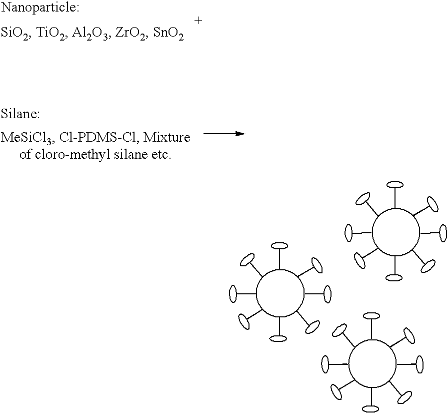

Silane and siloxane monolayers or oligolayers are covalently attached to the —OH groups of inorganic nanoparticles. The hydrophobic nanoparticles can be physically mixed with a 1 component (1K) clearcoat. TABLE 3 lists examples of the kinds of nanoparticles and silanes used. Additionally, a method of calculating the amount of silane/siloxane needed to be added to the nanoparticles is also displayed in the table.

TABLE 3

| Nanoparticle | Particle | | |
|---|---|---|---|
| Type | Size | BET Surface Area | Silane |
| OX 50 | 40 nm | 50 m2/g | Cl-PDMS-Cl |
| | | | Mixture of Cl-PDMS-Cl |
| | | | and tris TMS MeSiCl3 |
| | | | Flourinated Alkyl Silane |
| | | | (C3 and C6) |
| Aerosil 200 | 12 nm | 200 m2/g | Cl-PDMS-Cl |
| | | | Mixture of Cl-PDMS-Cl |
| | | | and tris TMS MeSiCl3 |
| | | | Flourinated Alkyl Silane |
| | | | (C3 and C6) |
| Aerosil 380 | 7 nm | 380 m2/g | Cl-PDMS-Cl |
| | | | Mixture of Cl-PDMS-Cl |
| | | | and tris TMS MeSiCl3 |
| | | | Flourinated Alkyl Silane |
| | | | (C3 and C6) |

Calculation method to determine amount of
Silane needed for reaction.
Example: Reaction of OX 50 Silica powder
With Cl-PDMS-Cl.

| OX 50 | Cl-PDMS-Cl |
|---|---|
| Number of OH | Molecular weight |
| groups/nm² = 3 | M = 2000-4000 |
| BET surface | Number of reactive |
| area = 50 m²/gm | Chlorine/ml = (2 × 6.023 × 10²³)/M |
| Number of OH groups | Number of reactive |
| Per W gram = | Chlorine per L ml = |
| 3 × 50 × W × 10¹⁸ | (2 × 6.023 × 10²³ × L)/M |

The above listed materials were used in the example presented below: Chloroalkylsilanes (MenSiCl4-n) Where n=0-3 (Gelest Catalog: SID4120.1, SIM6520.1, SIT 8510.1)(2) Chlorine terminated polydimethyle siloxane (Molecular weight 2000-40000) (Gelest Catalog: DMS-K13)(3) Tris Trimethyle siloxane (Gelest Catalog: SIT 8719.5). The following process of surface modification was used with the examples listed above. First the nanoparticles were dispersed in Toluene using an ultrasonic bath, where silane/siloxane or their mixture was quickly injected by syringe. Silane or siloxanes may be terminated with monofunctional or difunctional chlorine, silanol, or hydroxyl groups or may include amino, epoxy, diacetoxymethyl, dimethylamino, ethoxy, and methoxy type functional groups. Fluorinated silane/Siloxane may also used. Surface modification of the nanoparticles was carried out in a mechanical shaker for 8-10 hours at 60° C. A catalyst such as EDIPA (Ethyldiisopropylamine) can be used to promote faster reaction and high reaction yield. The surface modified particles were then washed several times to remove the unreacted silane and suspended in non-polar solvents before incorporating into the clear coat material.

FIG. 7 shows two tests to observe the water repellency of the surface modified nanoparticles. The top left and right images represent the behavior of a water drop on a thin layer of unmodified and modified nanoparticle, respectively. The surface modified particles clearly display water drop beads, while the unmodified particles display a flattened puddle.

A second test was conducted and is depicted in the bottom portion of FIG. 7. Bottle (a) contains unmodified particles while (b) and (c) contains particles modified with chlorinated PDMS and tri-chloro methyl silane, respectfully. Each bottle was half filled with water with the remainder filled with Toluene. Since Toluene is a non polar liquid and lighter than water, it does not dissolve in water and stays on the upper top half of the bottle. Unmodified (a) particles stayed in the water phase due to its polar characteristics, while modified nanoparticles (b) and (c) move to the non polar Toluene phase. This separation indicates that the modified nanoparticles are surface modified with a non-polar group.

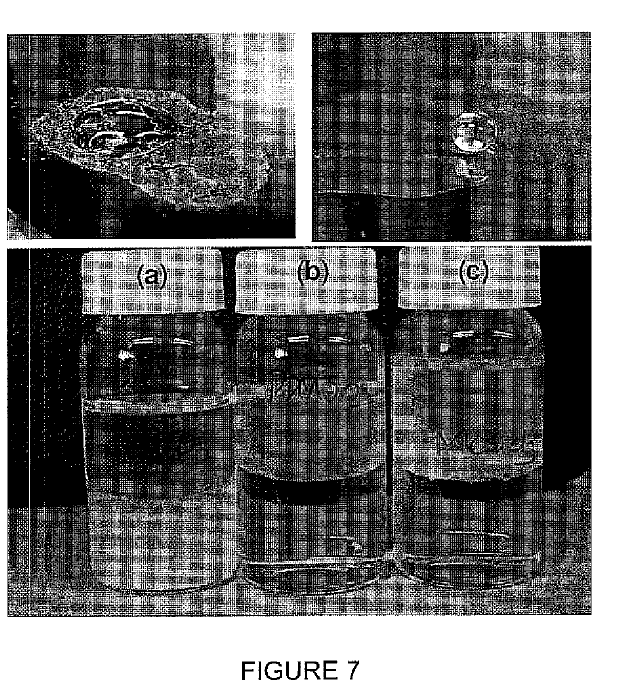

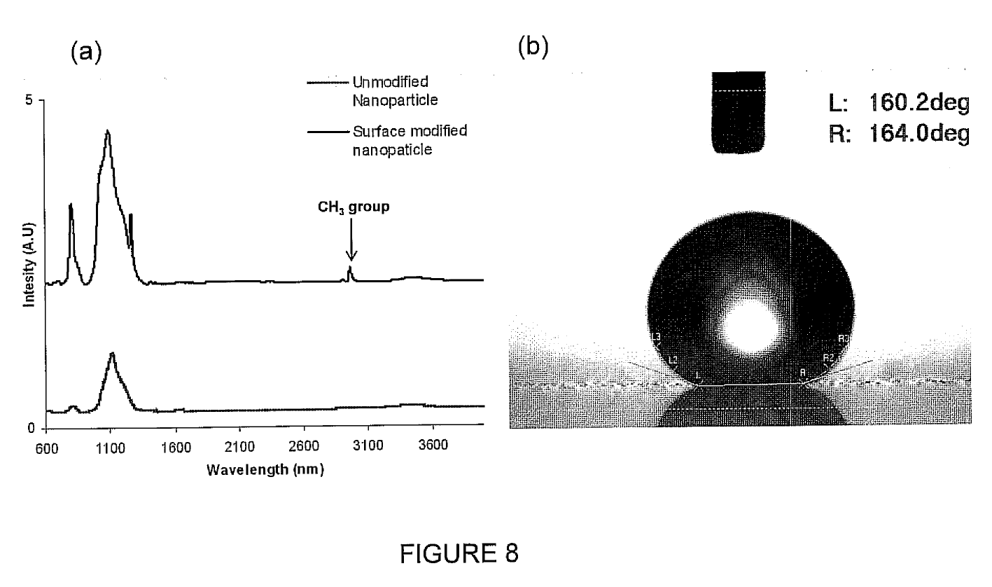

In addition to the tests outlined above, the dried modified nanoparticles were examined using IR spectroscopy. FIG. 8 (a) shows the IR spectroscopy of the dried modified nanoparticles. The modified particle shows a strong peak at around the 2900 nm wavelength which corresponds to stretching of C and H bonds. Such a peak is absent in unmodified particles. A contact angle measurement of the modified nanoparticle loaded clear coat had a contact angle of more than 160 degree as shown the FIG. 8(b).

### Example 5

It was found that in order to design coatings with high contact angles a high loading of nanoparticles may be required, such as over 40% dry volume. Such a high loading of nanoparticles may lead to problems due to (1) high viscosity of the clearcoat when nanoparticles are added and (2) due to the high content of the solvent used to aid the nanoparticle dispersion in the clearcoat in addition to an existing solvent in the clear coat. For example, a 1K clear coat may typically contain over 60% solvent. In such a clear coat, the solid content in the clear coat mixture is often low, such as less than 20%. Such a low solid content 1 K system may have the problem of a sagging of the film when spread over the panels. A two part or 2K clear coat may be utilized. 2K clear coats may be used to produce a mechanically robust coating for exterior automotive paints. The 2K clear coat typically consists of two parts, where one part contains the main resin and the other part contains isocyanides needed for crosslinking of the paint film. Nanoparticles may be added in either of the parts and applied on the panel either by drawing down the film or using a spray process. The paint film was cured at 120° F. for 8 hours.

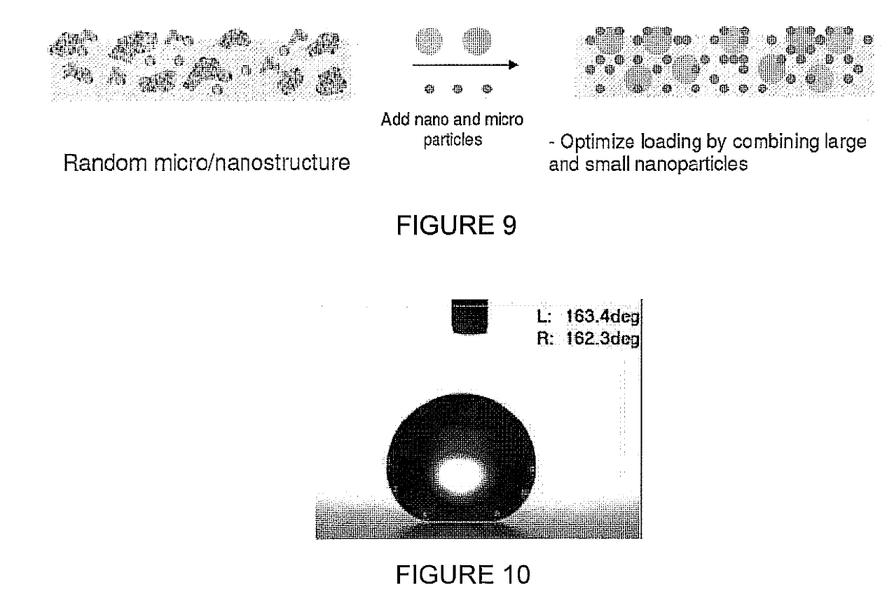

Additionally, a combination of different sized nanoparticles was used. The combination of different sized nanoparticles may be used to achieve a higher contact angle at a lower nanoparticle loading volume. A schematic of the combination of the different sized particles is shown in FIG. 9. Various mixing ratios of an aggregated LE3 sample having one size characteristic and a modified A380 sample having another size characteristic were used and are displayed in table 4. The wet percentage is defined as the nanoparticle containing 2K clear coat including the solvent added in order to disperse the nanoparticles. Solvents present in the clear coat were not included in the wet percentage.

As can be seen in table 4, in the 2K system, 20 wet % LE3 generates a contact angle of about 139° where as 20 wet % mixed nanoparticles with 14% and 6% combination of LE3 and surface modified A380 shows superhydrophobic behavior reaching a contact angle over 160°, as shown in FIG. 10.

TABLE 4

| Particle Type | Wet Wt % | CA | Transparency | Rolling Off |
|---|---|---|---|---|
| LE3 | 10 | 97.8 | 56.2 | No |
| LE3 | 20 | 139 | 41.3 | No |
| LE3/Modified A380 | 10/2 | 99.7 | 57.1 | No |
| LE3/Modified A380 | 10/6 | 131 | 53.5 | No |
| LE3/Modified A380 | 10/10 | 138 | 50.9 | No |
| LE3/Modified A380 | 14/6 | 163.1 | — | Yes |

The invention has been described in an illustrative manner. It is to be understood that the terminology, which has been used, is intended to be in the nature of words of description rather than limitation. Many modifications and variations of the invention are possible in light of the above teachings. Therefore, within the scope of the appended claims, the invention may be practiced other than as specifically described.

1. A process of forming a clear coat comprising:
providing hydrophobic nanoparticles;
dispersing the hydrophobic nanoparticles in a solvent;
combining the dispersed nanoparticles in the solvent with a clear coat material;
mixing the dispersed nanoparticles in the solvent with the clear coat material forming a clear coat having a transparency of at least 50 percent.

2. The process of claim 1 wherein the clear coat has a contact angle of at least 130 degrees.

3. The process of claim 1 wherein the clear coat has a nanoparticle concentration of from 20 to 60 percent by volume.

4. The process of claim 1 wherein the nanoparticles have a size of from 5 to 5000 nanometers.

5. The process of claim 1 wherein the clear coat material includes a first part and a second part, the hydrophobic nanoparticles dispersed in either of the first part or the second part.

6. The process of claim 1 wherein the hydrophobic nanoparticles include different sized particles.

7. The process of claim 1 wherein the hydrophobic nanoparticles are formed by:
providing metal oxide or silicon oxide nanoparticles;
dispersing the nanoparticles in a solvent;
reacting the nanoparticles in the solvent with a surface modifying reactant forming hydrophobic nanoparticles; and
washing the hydrophobic nanoparticles removing excess reactants.

8. The process of claim 1 wherein the surface modifying reactant is selected from the group consisting of:
silanes, siloxanes and silazanes.

9. The process of claim 8 wherein the surface modifying reactant forms a non-polar group attached to the nanoparticle.

10. The process of claim 1 wherein the solvent is a non-polar solvent.

11. A clear coat composition comprising:
a first component including hydrophobic nanoparticles mixed with a second component including a clear coat material forming a hydrophobic clear coat having a transparency of at least 50 percent.

12. The clear coat composition of claim 11 wherein the clear coat has a contact angle of at least 130 degrees.

13. The clear coat composition of claim 11 wherein the clear coat has a nanoparticle concentration of from 20 to 60 percent by volume.

14. The clear coat composition of claim 11 wherein the nanoparticles have a size of from 5 to 5000 nanometers.

15. The clear coat composition of claim 11 wherein the clear coat material includes a first part and a second part, the hydrophobic nanoparticles dispersed in either of the first part or the second part.

16. The clear coat composition of claim 11 wherein the hydrophobic nanoparticles include different sized particles.

17. The clear coat composition of claim 11 wherein the hydrophobic nanoparticles include metal oxide or silicon oxide nanoparticles having a surface modifying group attached to the nanoparticle, the surface modifying group selected from the group consisting of:
silanes, siloxanes and silazanes.

18. The clear coat composition of claim 11 wherein the hydrophobic nanoparticles are dispersed in a solvent.

19. A paint system comprising:
a substrate material;
a base coat applied to the substrate material;
a clear coat layer applied to the base coat, the clear coat including a first component including hydrophobic nanoparticles mixed with a second component including a clear coat material forming a hydrophobic clear coat having a transparency of at least 50 percent.

20. The paint system of claim 19 wherein the clear coat has a contact angle of at least 130 degrees.

21. The paint system of claim 19 wherein the clear coat has a nanoparticle concentration of from 20 to 60 percent by volume.

22. The paint system of claim 19 wherein the nanoparticles have a size of from 5 to 5000 nanometers.

23. The paint system of claim 19 wherein the clear coat material includes a first part and a second part, the hydrophobic nanoparticles dispersed in either of the first part or the second part.

24. The paint system of claim 19 wherein the hydrophobic nanoparticles include different sized particles.

25. The paint system of claim 19 wherein the hydrophobic nanoparticles include metal oxide or silicon oxide nanoparticles having a surface modifying group attached to the nanoparticle, the surface modifying group selected from the group consisting of:
silanes, siloxanes and silazanes.

26. The paint system of claim 19 wherein the hydrophobic nanoparticles are dispersed in a solvent.
